(19) United States
(12) Patent Application Publication
(10) Pub. No.: US 2010/0266958 A1
(43) Pub. Date: Oct. 21, 2010

(54) RESIST MATERIAL AND METHOD FOR FORMING PATTERN USING THE SAME

(75) Inventors: Masayuki ENDOU, Osaka (JP); Masaru Sasago, Osaka (JP)

Correspondence Address: MCDERMOTT WILL & EMERY LLP, 600 13TH STREET, NW, WASHINGTON, DC, 20005-3096, US

(73) Assignee: PANASONIC CORPORATION, Osaka (JP)

(21) Appl. No.: 12/829,132

(22) Filed: Jul. 1, 2010

Related U.S. Application Data
(63) Continuation of application No. PCT/JP2009/003259, filed on Jul. 10, 2009.

(30) Foreign Application Priority Data
Oct. 2, 2008 (JP) 2008-257626

(51) Int. Cl. G03F 7/20; G03F 7/004

(52) U.S. Cl. 430/286.1; 430/270.1; 430/325; 430/296

(57) ABSTRACT

Initially, on a substrate, a resist film is formed from a resist material including a monomer containing a halogen atom (fluorine) and stable to acid, a polymer containing fluorine and stable to acid, a polymer containing an acid-labile group, and a photo acid generator. Next, while liquid is provided on the resist film, pattern exposure is performed by selectively irradiating the resist film with exposing light. Next, the resist film after the pattern exposure is developed to form a resist pattern from the resist film.

### CROSS-REFERENCE TO RELATED APPLICATIONS

This is a continuation of PCT International Application PCT/JP2009/003259 filed on Jul. 10, 2009, which claims priority to Japanese Patent Application No. 2008-257626 filed on Oct. 2, 2008. The disclosures of these applications including the specifications, the drawings, and the claims are hereby incorporated by reference in their entirety.

### BACKGROUND

The present disclosure relates to resist materials used in semiconductor device fabrication processes and the like, and methods for forming a pattern using the resist materials.

There is a demand for rapid advances in lithography technology in order to increase the scale of integration of semiconductor integrated circuits and reduce the sizes of semiconductor devices. At present, pattern formation is performed by photolithography using, as an exposing light source, a mercury lamp, a KrF excimer laser, an ArF excimer laser, or the like. The use of an F₂ laser having a shorter wavelength was contemplated, but the development of the laser is now abandoned because there are still many problems with exposure apparatuses and resist materials.

Under such circumstances, immersion lithography has been recently proposed in order to provide finer patterns using conventional exposing light (see, for example, M. Switkes and M. Rothschild, “Immersion lithography at 157 nm,” J. Vac. Sci. Technol., Vol. B19, P. 2353 (2001)). In immersion lithography, because a gap between a projection lens of an exposure apparatus and a resist film on a wafer is filled with liquid (immersion liquid) which has a refractive index of n (where n>1), the numerical aperture (NA) of the exposure apparatus is increased to n·NA, whereby the resolution capability of the resist film is improved.

A version of immersion lithography has been proposed in which a barrier film for hindering or preventing interaction between the resist film and the immersion liquid is provided on the resist film. However, the provision of the barrier film requires additional materials and steps for formation of the barrier film, resulting in an increase in the manufacturing cost, which is a problem. Therefore, there is a demand for a resist process which does not require a barrier film.

To meet the demand, a resist which does not require a barrier film has been proposed where a fluorine-containing polymer or the like is added to the resist and is segregated into a surface of the resist film (see, for example, Japanese Patent Publication No. 2006-309245).

The method of adding a fluorine-containing polymer or the like into a resist has the effect of improving the hydrophobicity of the surface of the resist film to hinder or prevent the interaction between the resist film and the immersion liquid.

A conventional pattern formation method employing immersion lithography where a barrier film is not provided will be described hereinafter with reference to FIGS. 7A-7D.

Initially, a chemically-amplified positive resist material is prepared which has the following composition.

| | | |
|---|---|---|
| Base polymer: poly((t-butyl-norbornene-5- | 2 | g |
| methylenecarboxylate) (50 mol %)-(maleic anhydride) | | |
| (50 mol %)) | | |
| Fluorine-containing polymer: poly(perfluoroethyl acrylate) | 0.2 | g |
| Acid generator: triphenylsulfonium trifluoromethanesulfonic | 0.05 | g |
| acid | | |
| Quencher: triethanolamine | 0.002 | g |
| Solvent: propylene glycol monomethyl ether acetate | 20 | g |

Next, as shown in FIG. 7A, the chemically-amplified resist material is applied onto a substrate 1 to form a resist film 2 having a thickness of 0.12 μm.

Next, as shown in FIG. 7B, immersion liquid 3 which is water is provided on the resist film 2 before pattern exposure is performed by irradiating the resist film 2 through a mask 4 with exposing light emitted by an ArF excimer laser with an NA of 1.07.

Next, as shown in FIG. 7C, the resist film 2 after the pattern exposure is heated using a hot plate at a temperature of 105° C. for 60 sec.

Next, the heated resist film 2 is developed using a tetramethylammonium hydroxide developer having a concentration of 2.38 wt %. As a result, as shown in FIG. 7D, a resist pattern 2b is formed which is an unexposed portion of the resist film 2 and has a line width of 0.06 μm.

### SUMMARY

However, as shown in FIG. 7D, in the resist pattern 2b obtained by the conventional pattern formation method, the resolution capability of the resist is deteriorated, resulting in a defective pattern shape, which is a problem.

If the resist pattern 2b having a defective pattern shape due to the deterioration of the resolution capability of the resist is used to etch a target film, a defective pattern shape is also formed in the target film, resulting in a reduction in the productivity and yield of the process of fabricating a semiconductor device, which is a problem.

In view of the aforementioned problems, the detailed description describes implementations of a technique capable of improving the resolution capability of a resist material used in lithography in which a barrier film is not provided on a resist film, thereby hindering or preventing a defective pattern from occurring.

The present inventors have studied in many ways the conventional immersion lithography which employs a process which does not use a barrier film. As a result, the present inventors have found that, as shown in FIG. 1B, the fluorine-containing polymer added to the resist material is segregated into an upper portion of the resist film 2 to form an uneven segregation portion 2a, and a component of the resist film 2 is dissolved into the immersion liquid and the immersion liquid permeates into the resist film 2, particularly in portions having a concave cross-section, i.e., having a smaller thickness than those of other portions, resulting in the deterioration of the resolution capability of the resist film 2. Here, the segregation portion 2a of the fluorine-containing polymer has an average thickness of about 10 nm.

The present inventors have also found that if a monomer or an organic low-molecular-weight compound containing a halogen atom is added to the resist film 2 in addition to the fluorine-containing polymer, the segregation portion 2a has substantially a uniform thickness as shown in FIG. 1A.

This may be because when the fluorine-containing polymer is segregated into the surface of the resist film when the resist is formed, the monomer or organic low-molecular-weight compound containing a halogen atom is inserted into uneven spaces between the polymer molecules to smooth the segregation portion 2a. The halogen atom, which has an electronegativity having a large absolute value, may cause the fluorine-containing polymer to easily move in the polar direction of the immersion liquid having a larger polarity than that of the resist or the polar direction of air during dry exposure, i.e., toward the surface of the resist film.

As a result, the fluorine-containing polymer is homogenized in the resist film, and therefore, the components of the resist film are hindered or prevented from being dissolved into the immersion liquid and the immersion liquid is hindered or prevented from permeating into the resist film, whereby a pattern having a satisfactory shape can be formed with high accuracy. Moreover, even when dry exposure is performed, a pattern having a satisfactory shape can be formed with high accuracy. Note that, in the present disclosure, the segregation layer has a thickness of as small as about 10 nm, and therefore, the solubility of the exposed portion during development remains good.

The monomer or organic low-molecular-weight compound containing a halogen atom and the fluorine-containing polymer are preferably stable to acid. This is because if a material which is labile to acid is used, the unexposed portion of the resist may react with acid which is generated and diffused after exposure, whereby the homogenous layer structure may collapse.

The organic low-molecular-weight compound containing a halogen atom of the present disclosure preferably has a molecular weight of 1000 or less. This is because if the molecular weight is 1000 or less, the organic low-molecular-weight compound containing a halogen atom is more easily inserted into the uneven spaces of the fluorine-containing polymer, whereby the effect of smoothing the segregation portion is enhanced.

The present disclosure has been made based on the aforementioned findings. The detailed description describes implementations of the following resist materials.

An first example resist material according to the present disclosure includes a monomer containing a halogen atom and stable to acid, a polymer containing fluorine and stable to acid, a polymer containing an acid-labile group, and a photo acid generator.

According to the first example resist material, the monomer containing a halogen atom and stable to acid is provided in addition to the polymer containing fluorine and stable to acid. Therefore, when a resist film is formed from the resist material, the polymer containing fluorine and stable to acid is segregated into an upper portion of the resist film, and in this case, the smoothing effect of the halogen atom-containing monomer allows the segregation portion to have a uniform thickness. Therefore, the segregation portion having the uniform thickness maintains the barrier capability to improve the resolution capability of the resist film, whereby a defective pattern shape can be reduced or prevented.

A second example resist material according to the present disclosure includes an organic low-molecular-weight compound with a molecular weight of 1000 or less containing a halogen atom and stable to acid, a polymer containing fluorine and stable to acid, a polymer containing an acid-labile group, and a photo acid generator.

According to the second example resist material, the organic low-molecular-weight compound with a molecular weight of 1000 or less containing a halogen atom and stable to acid is provided in addition to the polymer containing fluorine and stable to acid. Therefore, when a resist film is formed from the resist material, the polymer containing fluorine and stable to acid is segregated into an upper portion of the resist film, and in this case, the smoothing effect of the halogen atom-containing organic low-molecular-weight compound allows the segregation portion to have a uniform thickness. Therefore, the segregation portion having the uniform thickness maintains the barrier capability to improve the resolution capability of the resist film, whereby a defective pattern shape can be reduced or prevented.

In the first or second example resist material, the halogen atom may be fluorine, chlorine, bromine, or iodine.

In this case, the halogen atom may be fluorine, and the monomer containing fluorine and stable to acid may be perfluoro(propyl vinyl ether), 2,2,2-trifluoroethyl acrylate, 2,2,2-trifluoroethyl methacrylate, 2,2,3,3-tetrafluoropropyl acrylate, 1H,1H,5H-octafluoropentyl acrylate, 1H,1H,5H-octafluoropentyl methacrylate, perfluoroethyl acrylate, vinylhexafluoroisopropyl alcohol, α-trifluoromethyl acrylate, or norbornene-5-methylenehexafluoroisopropyl alcohol.

When the halogen atom is chlorine, the monomer containing chlorine and stable to acid may be methyl methacrylate chloride or methylacrylate chloride.

When the halogen atom is bromine, the monomer containing bromine and stable to acid may be bromomethyl methacrylate or methylacrylate bromide.

When the halogen atom is iodine, the monomer containing iodine and stable to acid may be methyl methacrylate iodide or methylacrylate iodide.

When the halogen atom is fluorine, the organic low-molecular-weight compound with a molecular weight of 1000 or less containing fluorine and stable to acid may be perfluoro-n-butanecarboxylic acid, perfluoro-n-hexanecarboxylic acid, perfluoroacetone, 3,4-difluorobenzyl alcohol, or perfluorotripropylamine.

When the halogen atom is chlorine, the organic low-molecular-weight compound with a molecular weight of 1000 or less containing chlorine and stable to acid may be dichloromethane or hypochlorous acid.

When the halogen atom is bromine, the organic low-molecular-weight compound with a molecular weight of 1000 or less containing bromine and stable to acid may be 2,3-dibromopropanol, bromoacetyl bromide, dibromosuccinic acid, or α-bromo-γ-butyllactone.

When the halogen atom is iodine, the organic low-molecular-weight compound with a molecular weight of 1000 or less containing iodine and stable to acid may be diphenyliodonium nitrate or diphenyliodonium iodide.

In the first or second example resist material, the polymer containing fluorine and stable to acid may be poly(perfluoroethyl acrylate), polyvinylhexafluoroisopropyl alcohol, poly(α-trifluoromethyl acrylate), or poly(norbornene-5-methylenehexafluoroisopropyl alcohol).

In the first resist material, the monomer containing fluorine and stable to acid is preferably a constitutional unit of the polymer containing fluorine and stable to acid.

In this case, the halogen atom-containing monomer and the fluorine-containing polymer have good compatibility.

In the first example resist material, the acid-labile group may be t-butyl, t-butyloxycarbonyl, methoxymethyl, or 2-methyladamantyl.

In the first or second example resist material, the content of the fluorine-containing polymer is preferably about 5 wt % or more and about 20 wt % or less with respect to the polymer containing an acid-labile group, more preferably about 5 wt % or more and about 15 wt % or less.

In the first or second example resist material, if the content of the monomer containing a halogen atom and stable to acid is preferably about 5 wt % or more and about 30 wt % or less with respect to the polymer containing fluorine and stable to acid, a sufficient advantage can be achieved. More preferably, the content of the monomer containing a halogen atom and stable to acid is preferably about 10 wt % or more and about 20 wt % or less.

A first example method for forming a pattern according to the present disclosure includes the steps of forming, on a substrate, a resist film made of a resist material including a monomer containing a halogen atom and stable to acid, a polymer containing fluorine and stable to acid, a polymer containing an acid-labile group, and a photo acid generator, performing pattern exposure by selectively irradiating the resist film with exposing light while liquid is provided on the resist film, and developing the resist film after the pattern exposure to form a resist pattern from the resist film.

A second example method for forming a pattern according to the present disclosure includes the steps of forming, on a substrate, a resist film made of a resist material including a monomer containing a halogen atom and stable to acid, a polymer containing fluorine and stable to acid, a polymer containing an acid-labile group, and a photo acid generator, performing pattern exposure by selectively irradiating the resist film with exposing light, and developing the resist film after the pattern exposure to form a resist pattern from the resist film.

According to the first or second example pattern formation method, the monomer containing a halogen atom and stable to acid is provided in addition to the polymer containing fluorine and stable to acid. Therefore, when the resist film is formed, the polymer containing fluorine and stable to acid is segregated into an upper portion of the resist film, and in this case, the smoothing effect of the halogen atom-containing monomer allows the segregation portion to have a uniform thickness. Therefore, the segregation portion having the uniform thickness maintains the barrier capability to improve the resolution capability of the resist film, whereby a defective pattern shape can be reduced or prevented.

A third example method for forming a pattern according to the present disclosure includes the steps of forming, on a substrate, a resist film made of a resist material including an organic low-molecular-weight compound with a molecular weight of 1000 or less containing a halogen atom and stable to acid, a polymer containing fluorine and stable to acid, a polymer containing an acid-labile group, and a photo acid generator, performing pattern exposure by selectively irradiating the resist film with exposing light while liquid is provided on the resist film, and developing the resist film after the pattern exposure to form a resist pattern from the resist film.

A fourth example method for forming a pattern according to the present disclosure includes the steps of forming, on a substrate, a resist film made of a resist material including an organic low-molecular-weight compound with a molecular weight of 1000 or less containing a halogen atom and stable to acid, a polymer containing fluorine and stable to acid, a polymer containing an acid-labile group, and a photo acid generator, performing pattern exposure by selectively irradiating the resist film with exposing light, and developing the resist film after the pattern exposure to form a resist pattern from the resist film.

According to the third or fourth example pattern formation method, the organic low-molecular-weight compound with a molecular weight of 1000 or less containing a halogen atom and stable to acid is provided in addition to the polymer containing fluorine and stable to acid. Therefore, when the resist film is formed, the polymer containing fluorine and stable to acid is segregated into an upper portion of the resist film, and in this case, the smoothing effect of the halogen atom-containing organic low-molecular-weight compound allows the segregation portion to have a uniform thickness. Therefore, the segregation portion having the uniform thickness maintains the barrier capability to improve the resolution capability of the resist film, whereby a defective pattern shape can be reduced or prevented.

In the first or third example pattern formation method, the liquid may be water.

In the first or third pattern formation method, the liquid may be an acidic solution.

In this case, the acidic solution may be aqueous cesium sulfate solution or aqueous phosphoric acid solution.

In the first or third example pattern formation method, the exposing light for immersion exposure may be KrF excimer laser light, Xe₂ laser light, ArF excimer laser light, F₂ laser light, KrAr laser light, or Ar₂ laser light.

In the second or fourth example pattern formation method, the exposing light for dry exposure may be KrF excimer laser light, Xe₂ laser light, ArF excimer laser light, F₂ laser light, KrAr laser light, Ar₂ laser light, extreme ultraviolet, or an electron beam.

According to the example resist materials of the present disclosure and the example pattern formation methods using the example resist materials, the resolution capability of the resist material can be improved without the need of a barrier film on the resist film, resulting in a fine pattern having a satisfactory shape.

### BRIEF DESCRIPTION OF THE DRAWINGS

FIG. 1A is a cross-sectional view schematically showing a resist film for describing the concept of the present disclosure.

FIG. 1B is a cross-sectional view schematically showing a conventional resist film where a barrier film is not used.

FIGS. 2A-2D are cross-sectional views showing steps of a method for forming a pattern according to a first embodiment of the present disclosure.

FIGS. 3A-3D are cross-sectional views showing steps of a method for forming a pattern according to a second embodiment of the present disclosure.

FIGS. 4A-4D are cross-sectional views showing steps of a method for forming a pattern according to a third embodiment of the present disclosure.

FIGS. 5A-5D are cross-sectional views showing steps of a method for forming a pattern according to a fourth embodiment of the present disclosure.

FIGS. 6A-6D are cross-sectional views showing steps of a method for forming a pattern according to a fifth embodiment of the present disclosure.

FIGS. 7A-7D are cross-sectional views showing steps of a conventional method for forming a pattern.

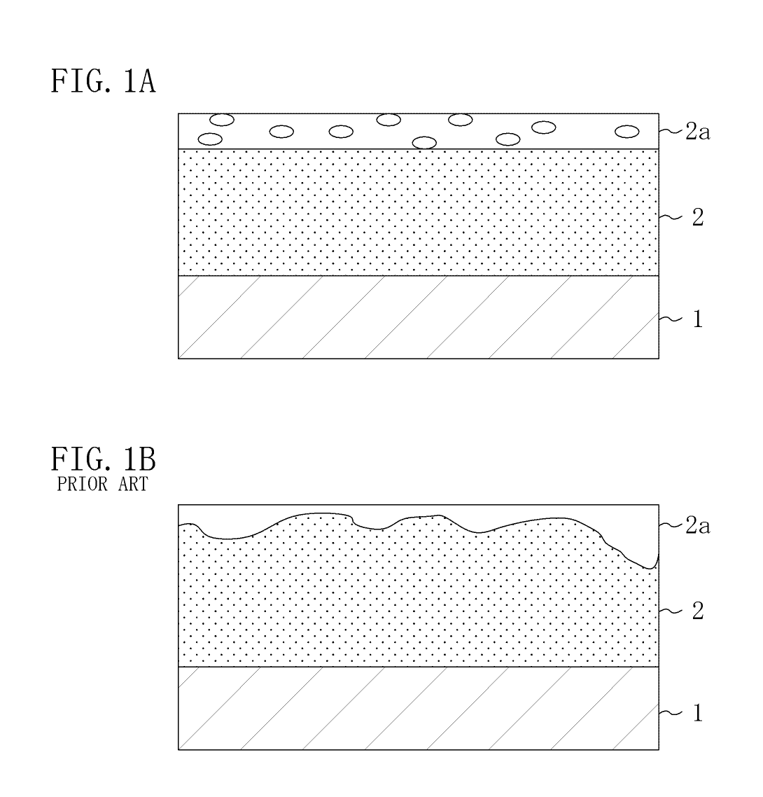

### DETAILED DESCRIPTION

### First Embodiment

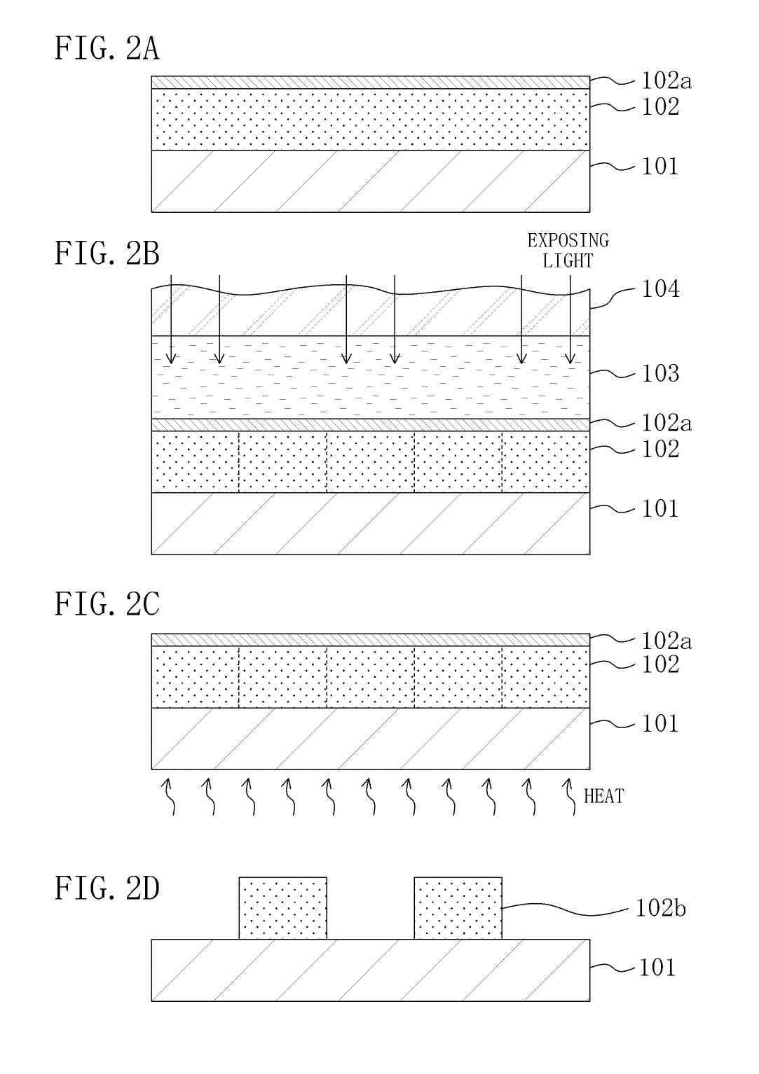

A method for forming a pattern according to a first embodiment of the present disclosure will be described with reference to FIGS. 2A-2D.

Initially, a chemically-amplified positive resist material is prepared which has the following composition.

| | | |
|---|---|---|
| Polymer containing an acid-labile group (base polymer): | 2 | g |
| poly((t-butyl-norbornene-5-methylenecarboxylate) (50 mol | | |
| %)-(maleic anhydride) (50 mol %)) | | |
| Fluorine-containing polymer stable to acid: | 0.2 | g |
| poly(perfluoroethyl acrylate) | | |
| Monomer containing a halogen atom stable to acid: | 0.03 | g |
| perfluoroethyl acrylate | | |
| Photo acid generator: | 0.05 | g |
| triphenylsulfonium trifluoromethanesulfonic acid | | |
| Quencher: triethanolamine | 0.002 | g |
| Solvent: propylene glycol monomethyl ether acetate | 20 | g |

Next, as shown in FIG. 2A, the chemically-amplified resist material is applied onto a substrate 101 to form a resist film 102 having a thickness of 0.12 μm. In this case, the polymer containing fluorine and stable to acid, to which the monomer containing a halogen atom (fluorine) and stable to acid is added, is homogeneously segregated into an upper portion of the resist film 102 to form a segregation portion 102a. Here, the segregation portion 102a has a thickness of about 10 nm.

Next, as shown in FIG. 2B, immersion liquid 103 which is water is provided between the resist film 102 and a projection lens 104 by, for example, a puddle method. Pattern exposure is performed by irradiating the resist film 102 through the liquid 103 with exposing light emitted by an ArF excimer laser with an NA of 1.07 and then transmitted through a mask (not shown).

Next, as shown in FIG. 2C, the resist film 102 after the pattern exposure is heated using a hot plate at a temperature of 105° C. for 60 sec.

Next, the heated resist film 102 is developed using a 2.38-wt % tetramethylammonium hydroxide developer. As a result, as shown in FIG. 2D, a resist pattern 102b is obtained which is an unexposed portion of the resist film 102 and has a line width of 0.06 μm and a satisfactory shape.

Thus, the resist material of the first embodiment contains poly(perfluoroethyl acrylate), which is a polymer containing fluorine and stable to acid, and in addition, perfluoroethyl acrylate, which is a monomer containing a halogen atom and stable to acid. Therefore, when the resist film 102 is formed, poly(perfluoroethyl acrylate) is segregated into an upper portion of the resist film 102. In this case, the smoothing effect of perfluoroethyl acrylate allows the segregation portion 102a to have a uniform thickness. Therefore, the segregation portion 102a having the uniform thickness maintains the barrier capability against the resist film 102 and the liquid 103, whereby the resolution capability of the resist film 102 is improved and therefore a defective pattern shape can be hindered or prevented from occurring.

Moreover, perfluoroethyl acrylate, which is a monomer containing fluorine and stable to acid, is the constitutional unit of poly(perfluoroethyl acrylate), which is a polymer containing fluorine and stable to acid. Therefore, the monomer containing a halogen atom and the fluorine-containing polymer have good compatibility, whereby the homogeneity and the thickness uniformity of the segregation portion 102a are further improved.

### Second Embodiment

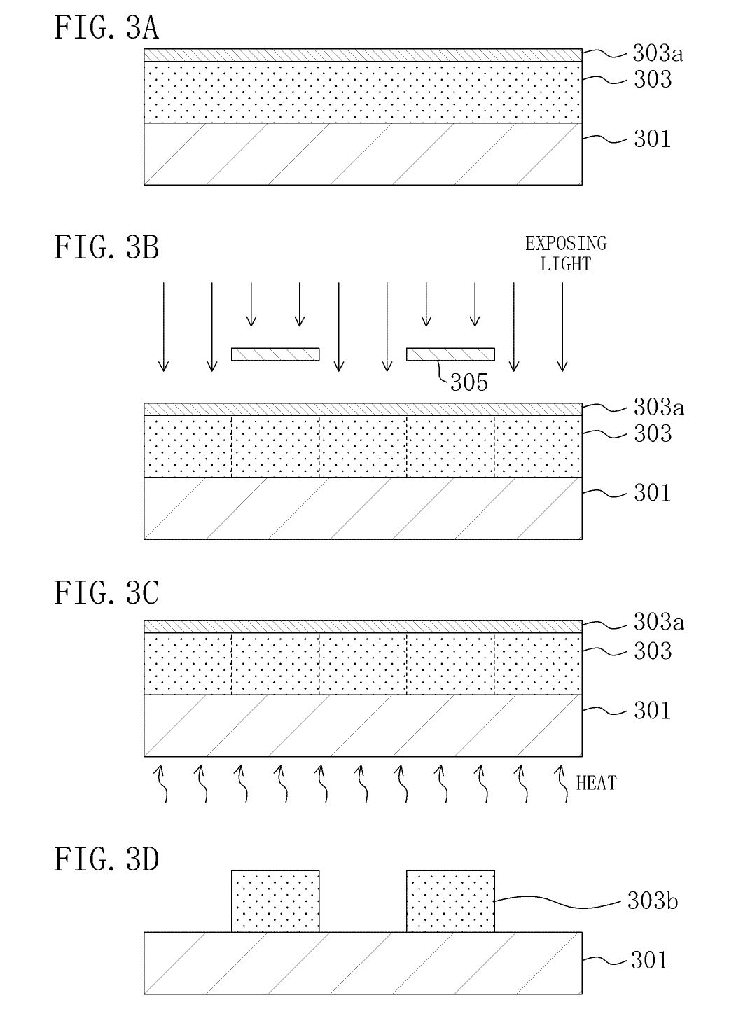

A method for forming a pattern according to a second embodiment of the present disclosure will be described hereinafter with reference to FIGS. 3A-3D.

Initially, a chemically-amplified positive resist material is prepared which has the following composition.

| | | |
|---|---|---|
| Polymer containing an acid-labile group (base polymer): | 2 | g |
| poly((t-butyl-norbornene-5-methylenecarboxylate) (50 mol | | |
| %)-(maleicanhydride) (50 mol %)) | | |
| Fluorine-containing polymer stable to acid: | 0.18 | g |
| poly(norbornene-5-methylenehexafluoroisopropyl alcohol) | | |
| Monomer containing a halogen atom stable to acid: | 0.032 | g |
| 2,2,2-trifluoroethyl acrylate | | |
| Photo acid generator: | 0.05 | g |
| triphenylsulfonium trifluoromethanesulfonic acid | | |
| Quencher: triethanolamine | 0.002 | g |
| Solvent: propylene glycol monomethyl ether acetate | 20 | g |

Next, as shown in FIG. 3A, the chemically-amplified resist material is applied onto a substrate 201 to form a resist film 202 having a thickness of 0.12 μm. In this case, the polymer containing fluorine and stable to acid, to which the monomer containing a halogen atom (fluorine) and stable to acid is added, is homogeneously segregated into an upper portion of the resist film 202 to form a segregation portion 202a. Here, the segregation portion 202a has a thickness of about 8 nm.

Next, as shown in FIG. 3B, pattern exposure is performed by irradiating the resist film 202 with exposing light emitted by an ArF excimer laser with an NA of 0.85 and then transmitted through a mask 205.

Next, as shown in FIG. 3C, the resist film 202 after the pattern exposure is heated using a hot plate at a temperature of 105° C. for 60 sec.

Next, the heated resist film 202 is developed using a 2.38-wt % tetramethylammonium hydroxide developer. As a result, as shown in FIG. 3D, a resist pattern 202b is obtained which is an unexposed portion of the resist film 202 and has a line width of 0.07 μm and a satisfactory shape.

Thus, the resist material of the second embodiment contains poly(norbornene-5-methylenehexafluoroisopropyl alcohol), which is a polymer containing fluorine and stable to acid, and in addition, 2,2,2-trifluoroethyl acrylate, which is a monomer containing a halogen atom and stable to acid. Therefore, when the resist film 202 is formed, poly(norbornene-5-methylenehexafluoroisopropyl alcohol) is segregated into an upper portion of the resist film 202. In this case, the smoothing effect of 2,2,2-trifluoroethyl acrylate allows the segregation portion 202a to have a uniform thickness. Therefore, the segregation portion 202a having the uniform thickness maintains the barrier capability against the resist film 202 and air, whereby the resolution capability of the resist film 202 is improved and therefore a defective pattern shape can be hindered or prevented from occurring.

### Third Embodiment

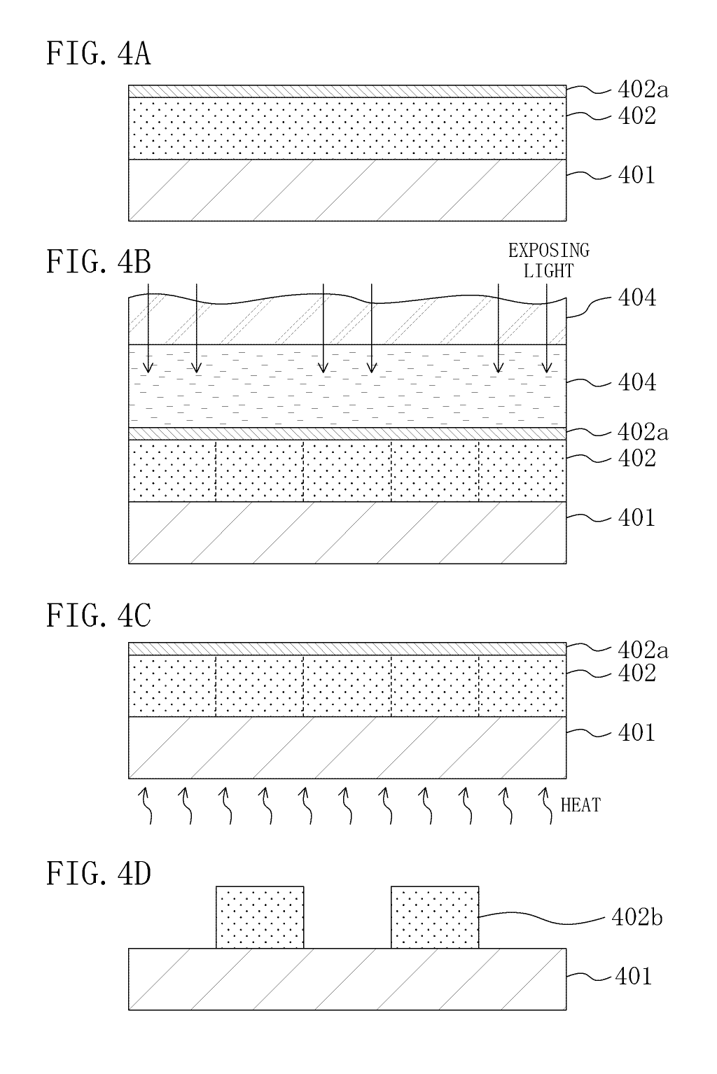

A method for forming a pattern according to a second embodiment of the present disclosure will be described hereinafter with reference to FIGS. 4A-4D.

Initially, a chemically-amplified positive resist material is prepared which has the following composition.

| | | |
|---|---|---|
| Polymer containing an acid-labile group (base polymer): | 2 | g |
| poly((t-butyl-norbornene-5-methylenecarboxylate) (50 mol | | |
| %)-(maleic anhydride) (50 mol %)) | | |
| Fluorine-containing polymer stable to acid: | 0.2 | g |
| poly(α-trifluoromethyl acrylate) | | |
| Monomer containing a halogen atom stable to acid: | 0.035 | g |
| bromomethyl methacrylate | | |
| Photo acid generator: | 0.05 | g |
| triphenylsulfonium trifluoromethanesulfonic acid | | |
| Quencher: triethanolamine | 0.002 | g |
| Solvent: propylene glycol monomethyl ether acetate | 20 | g |

Next, as shown in FIG. 4A, the chemically-amplified resist material is applied onto a substrate 301 to form a resist film 302 having a thickness of 0.12 μm. In this case, the polymer containing fluorine and stable to acid, to which the monomer containing a halogen atom (bromine) and stable to acid is added, is homogeneously segregated into an upper portion of the resist film 302 to form a segregation portion 302a. Here, the segregation portion 302a has a thickness of about 12 nm.

Next, as shown in FIG. 4B, immersion liquid 303 which is water is provided between the resist film 302 and a projection lens 304 by, for example, a puddle method. Pattern exposure is performed by irradiating the resist film 302 through the liquid 303 with exposing light emitted by an ArF excimer laser with an NA of 1.07 and then transmitted through a mask (not shown).

Next, as shown in FIG. 4C, the resist film 302 after the pattern exposure is heated using a hot plate at a temperature of 105° C. for 60 sec.

Next, the heated resist film 302 is developed using a 2.38-wt % tetramethylammonium hydroxide developer. As a result, as shown in FIG. 4D, a resist pattern 302b is obtained which is an unexposed portion of the resist film 302 and has a line width of 0.06 μm and a satisfactory shape.

Thus, the resist material of the third embodiment contains poly(α-trifluoromethyl acrylate), which is a polymer containing fluorine and stable to acid, and in addition, bromomethyl methacrylate, which is a monomer containing a halogen atom and stable to acid. Therefore, when the resist film 302 is formed, poly(α-trifluoromethyl acrylate) is segregated into an upper portion of the resist film 302. In this case, the smoothing effect of bromomethyl methacrylate allows the segregation portion 302a to have a uniform thickness. Therefore, the segregation portion 302a having the uniform thickness maintains the barrier capability against the resist film 302 and the liquid 303, whereby the resolution capability of the resist film 302 is improved and therefore a defective pattern shape can be hindered or prevented from occurring.

### Fourth Embodiment

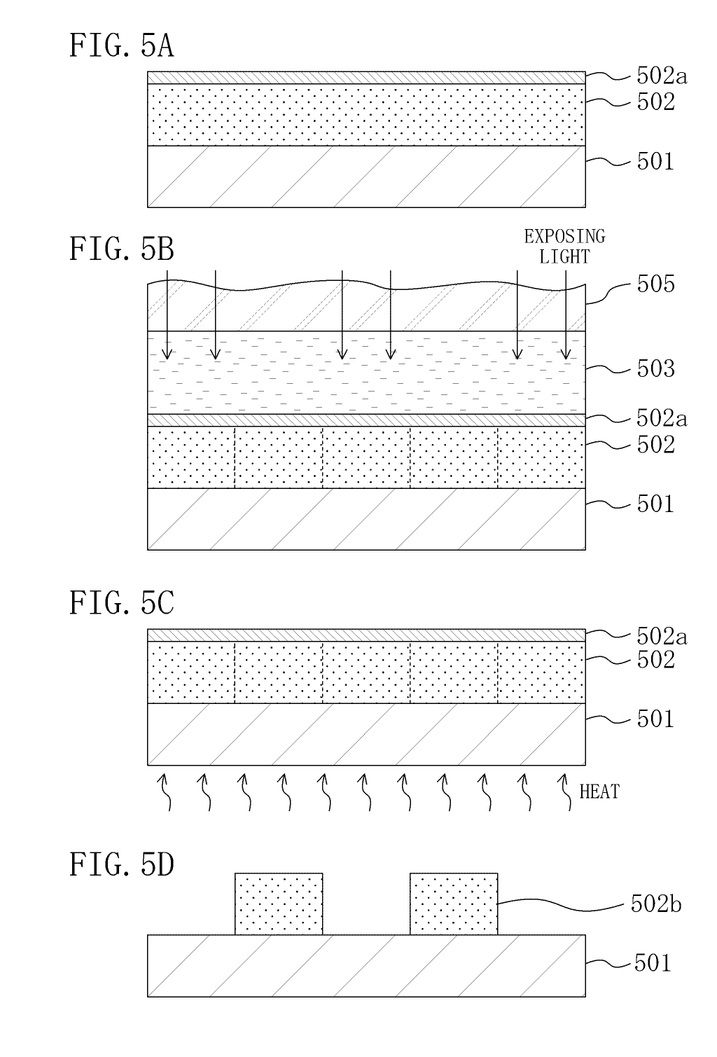

A method for forming a pattern according to a fourth embodiment of the present disclosure will be described hereinafter with reference to FIGS. 5A-5D.

Initially, a chemically-amplified positive resist material is prepared which has the following composition.

| | | |
|---|---|---|
| Polymer containing an acid-labile group (base polymer): | 2 | g |
| poly((t-butyl-norbornene-5-methylenecarboxylate) (50 mol | | |
| %)-(maleic anhydride) (50 mol %)) | | |
| Fluorine-containing polymer stable to acid: | 0.2 | g |
| poly(perfluoromethyl acrylate) | | |
| Halogen atom-containing organic low-molecular-weight | 0.038 | g |
| compound stable to acid: perfluoro-n-butanecarboxylic acid | | |
| Photo acid generator: | 0.05 | g |
| triphenylsulfonium trifluoromethanesulfonic acid | | |
| Quencher: triethanolamine | 0.002 | g |
| Solvent: propylene glycol monomethyl ether acetate | 20 | g |

Next, as shown in FIG. 5A, the chemically-amplified resist material is applied onto a substrate 401 to form a resist film 402 having a thickness of 0.12 μm. In this case, the polymer containing fluorine and stable to acid, to which the organic low-molecular-weight compound containing a halogen atom (fluorine) and stable to acid is added, is homogeneously segregated into an upper portion of the resist film 402 to form a segregation portion 402a. Here, the segregation portion 402a has a thickness of about 13 nm.

Next, as shown in FIG. 5B, immersion liquid 403 which is water is provided between the resist film 402 and a projection lens 404 by, for example, a puddle method. Pattern exposure is performed by irradiating the resist film 402 through the liquid 403 with exposing light emitted by an ArF excimer laser with an NA of 1.07 and then transmitted through a mask (not shown).

Next, as shown in FIG. 5C, the resist film 402 after the pattern exposure is heated using a hot plate at a temperature of 105° C. for 60 sec.

Next, the heated resist film 402 is developed using a 2.38-wt % tetramethylammonium hydroxide developer. As a result, as shown in FIG. 5D, a resist pattern 402b is obtained which is an unexposed portion of the resist film 402 and has a line width of 0.06 μm and a satisfactory shape.

Thus, the resist material of the fourth embodiment contains poly(perfluoromethyl acrylate), which is a polymer containing fluorine and stable to acid, and in addition, perfluoro-n-butanecarboxylic acid, which is an organic low-molecular-weight compound containing a halogen atom and stable to acid. Therefore, when the resist film 402 is formed, poly(perfluoromethyl acrylate) is segregated into an upper portion of the resist film 402. In this case, the smoothing effect of perfluoro-n-butanecarboxylic acid allows the segregation portion 402a to have a uniform thickness. Therefore, the segregation portion 402a having the uniform thickness maintains the barrier capability against the resist film 402 and the liquid 403, whereby the resolution capability of the resist film 402 is improved and therefore a defective pattern shape can be hindered or prevented from occurring.

### Fifth Embodiment

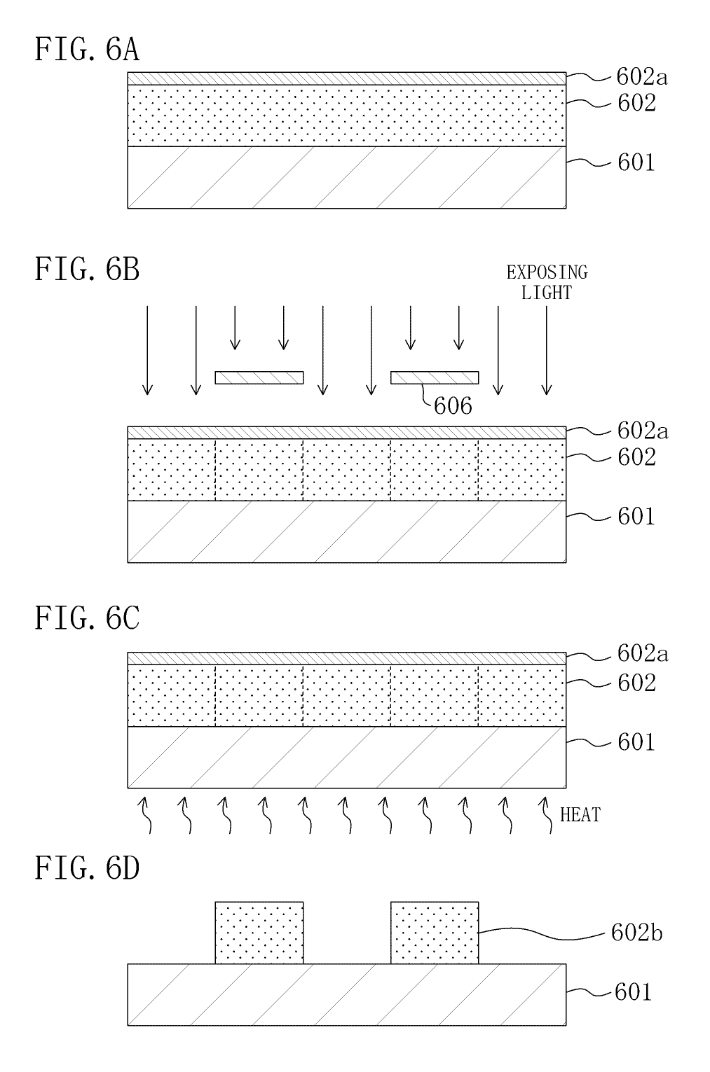

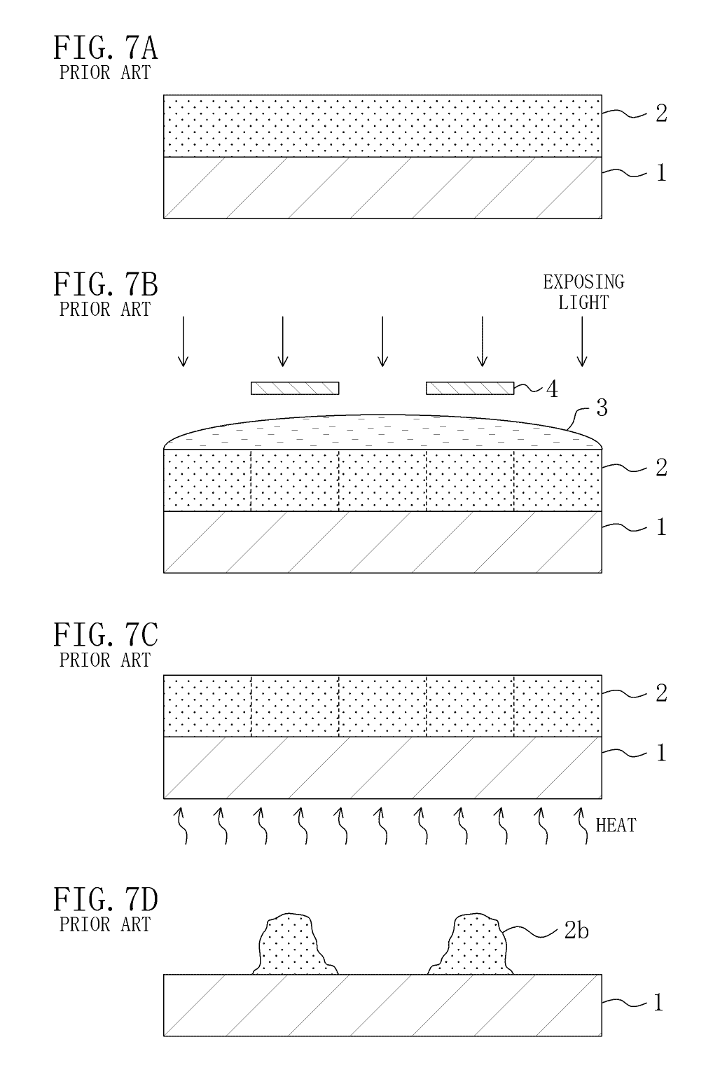

A method for forming a pattern according to a fifth embodiment of the present disclosure will be described hereinafter with reference to FIGS. 6A-6D.

Initially, a chemically-amplified positive resist material is prepared which has the following composition.

| | | |
|---|---|---|
| Polymer containing an acid-labile group (base polymer): | 2 | g |
| poly((t-butyl-norbornene-5-methylenecarboxylate) (50 mol | | |
| %)-(maleic anhydride) (50 mol %)) | | |
| Fluorine-containing polymer stable to acid: | 0.18 | g |
| poly(norbornene-5-methylenehexafluoroisopropyl alcohol) | | |
| Halogen atom-containing organic low-molecular-weight | 0.027 | g |
| compound stable to acid: α-bromo-γ-butyllactone | | |
| Photo acid generator: | 0.05 | g |
| triphenylsulfonium trifluoromethanesulfonic acid | | |
| Quencher: triethanolamine | 0.002 | g |
| Solvent: propylene glycol monomethyl ether acetate | 20 | g |

Next, as shown in FIG. 6A, the chemically-amplified resist material is applied onto a substrate 501 to form a resist film 502 having a thickness of 0.12 μm. In this case, the polymer containing fluorine and stable to acid, to which the organic low-molecular-weight compound containing a halogen atom (fluorine) and stable to acid is added, is homogeneously segregated into an upper portion of the resist film 502 to form a segregation portion 502a. Here, the segregation portion 502a has a thickness of about 9 nm.

Next, as shown in FIG. 6B, immersion pattern exposure is performed by irradiating the resist film 502 with exposing light emitted by an ArF excimer laser with an NA of 0.85 and then transmitted through a mask 505.

Next, as shown in FIG. 6C, the resist film 502 after the pattern exposure is heated using a hot plate at a temperature of 105° C. for 60 sec.

Next, the heated resist film 502 is developed using a 2.38-wt % tetramethylammonium hydroxide developer. As a result, as shown in FIG. 6D, a resist pattern 502b is obtained which is an unexposed portion of the resist film 502 and has a line width of 0.07 μm and a satisfactory shape.

Thus, the resist material of the fifth embodiment contains poly(norbornene-5-methylenehexafluoroisopropyl alcohol), which is a polymer containing fluorine and stable to acid, and in addition, α-bromo-γ-butyllactone, which is an organic low-molecular-weight compound containing a halogen atom and stable to acid. Therefore, when the resist film 502 is formed, poly(norbornene-5-methylenehexafluoroisopropyl alcohol) is segregated into an upper portion of the resist film 502. In this case, the smoothing effect of α-bromo-γ-butyllactone allows the segregation portion 502a to have a uniform thickness. Therefore, the segregation portion 502a having the uniform thickness maintains the barrier capability against the resist film 502 and air, whereby the resolution capability of the resist film 502 is improved and therefore a defective pattern shape can be hindered or prevented from occurring.

In the first to third embodiments, perfluoroethyl acrylate, 2,2,2-trifluoroethyl acrylate, or bromomethyl methacrylate is used as a monomer containing a halogen atom and stable to acid. The present disclosure is not limited to this. For example, when the halogen atom is fluorine, perfluoro(propyl vinyl ether), 2,2,2-trifluoroethyl methacrylate, 2,2,3,3-tetrafluoropropyl acrylate, 1H,1H,5H-octafluoropentyl acrylate, 1H,1H,5H-octafluoropentyl methacrylate, vinylhexafluoroisopropyl alcohol, α-trifluoromethyl acrylate, norbornene-5-methylenehexafluoroisopropyl alcohol, or the like can be used. When the halogen atom is chlorine, methyl methacrylate chloride, methylacrylate chloride, or the like can be used. When the halogen atom is bromine, methylacrylate bromide or the like can be used. When the halogen atom is iodine, methyl methacrylate iodide, methylacrylate iodide, or the like can be used.

In the fourth and fifth embodiments, perfluoro-n-butanecarboxylic acid or α-bromo-γ-butyllactone is used as an organic low-molecular-weight compound containing a halogen atom and stable to acid. The present disclosure is not limited to this. When the halogen atom is fluorine, perfluoro-n-hexanecarboxylic acid, perfluoroacetone, 3,4-difluorobenzyl alcohol, perfluorotripropylamine, or the like can be used as an organic low-molecular-weight compound with a molecular weight of 1000 or less which contains fluorine and is stable to acid. When the halogen atom is chlorine, dichloromethane, hypochlorous acid, or the like can be used. When the halogen atom is bromine, 2,3-dibromopropanol, bromoacetyl bromide, dibromosuccinic acid, or the like can be used. When the halogen atom is iodine, diphenyliodonium nitrate, diphenyliodonium iodide, or the like can be used.

In the first to fifth embodiments, poly(perfluoroethyl acrylate), poly(norbornene-5-methylenehexafluoroisopropyl alcohol), or poly(α-trifluoromethyl acrylate) is used as a polymer containing a halogen atom and stable to acid. The present disclosure is not limited to this. Poly(vinylhexafluoroisopropyl alcohol) or the like can be used. If a monomer containing fluorine and stable to acid is used as a constitutional unit of a polymer containing fluorine and stable to acid as in the first embodiment, the segregation portion 102a and the like are preferably allowed to be more homogeneous and have a uniform thickness.

Although the segregation portion has a thickness of about 8-13 nm in the first to fifth embodiments, the thickness of the segregation portion may take a value within the range of 5-15 nm as appropriate because the solubility of the component of the resist film into immersion liquid varies from component to component.

In the first to fifth embodiments, poly((t-butyl-norbornene-5-methylenecarboxylate) (50 mol %)-(maleic anhydride) (50 mol %)) is used as a polymer containing an acid-labile group which is the base polymer of the resist material. Alternatively, a t-butyloxycarbonyl group, a methoxymethyl group, or a 2-methyladamantyl group can be used instead of the t-butyl group, which is an acid-labile group.

In the first, third, and fourth embodiments in which immersion lithography is employed, water is used as the immersion liquid. Alternatively, an acidic solution, such as aqueous cesium sulfate solution (Cs₂SO₄) or aqueous phosphoric acid solution (H₃PO₄), may be used instead of water. A surfactant may be added to the immersion liquid.

The liquid is supplied onto the resist film by a puddle method in the foregoing embodiments. The present disclosure is not limited to this. Alternatively, other techniques may be used. For example, the substrate itself may be dipped into the liquid (dip method).

In the first, third, and fourth embodiments, ArF excimer laser light is used as the exposing light. Instead of this, KrF excimer laser light, Xe₂ laser light, F₂ laser light, KrAr laser light, or Ar₂ laser light may be used.

Also in the second and fifth embodiments in which dry exposure is employed, KrF excimer laser light, Xe₂ laser light, F₂ laser light, KrAr laser light, or Ar₂ laser light, or extreme ultraviolet or an electron beam may be used instead of ArF excimer laser light.

The polymer containing an acid-labile group (base polymer), the photo acid generator, the quencher, and the solvent which are components of the resist material of each embodiment are only for illustrative purposes. The chemically-amplified resist material can be made of other materials.

The chemically-amplified resist material may be negative instead of positive.

The resist material of the present disclosure and the method for forming a pattern using the resist material can provide a fine pattern having a satisfactory shape, and are useful for processes for fabricating semiconductor devices.

What is claimed is:

1. A resist material comprising:
a monomer containing a halogen atom and stable to acid;
a polymer containing fluorine and stable to acid;
a polymer containing an acid-labile group; and
a photo acid generator.

2. The resist material of claim 1, wherein
the halogen atom is fluorine, chlorine, bromine, or iodine.

3. The resist material of claim 2, wherein
the halogen atom is fluorine, and
the monomer containing fluorine and stable to acid is perfluoro(propyl vinyl ether), 2,2,2-trifluoroethyl acrylate, 2,2,2-trifluoroethyl methacrylate, 2,2,3,3-tetrafluoropropyl acrylate, 1H,1H,5H-octafluoropentyl acrylate, 1H, 1H,5H-octafluoropentyl methacrylate, perfluoroethyl acrylate, vinylhexafluoroisopropyl alcohol, α-trifluoromethyl acrylate, or norbornene-5-methylenehexafluoroisopropyl alcohol.

4. The resist material of claim 1, wherein
the polymer containing fluorine and stable to acid is poly(perfluoroethyl acrylate), polyvinylhexafluoroisopropyl alcohol, poly(α-trifluoromethyl acrylate), or poly(norbornene-5-methylenehexafluoroisopropyl alcohol).

5. The resist material of claim 1, wherein
the halogen atom is fluorine, and
the monomer is a constitutional unit of the polymer containing fluorine and stable to acid.

6. A resist material comprising:
an organic low-molecular-weight compound with a molecular weight of 1000 or less containing chlorine, bromine, or iodine and stable to acid, perfluoro-n-butanecarboxylic acid, perfluoro-n-hexanecarboxylic acid, perfluoroacetone, 3,4-difluorobenzyl alcohol, or perfluorotripropylamine;
a polymer containing fluorine and stable to acid;
a polymer containing an acid-labile group; and
a photo acid generator.

7. A method for forming a pattern, comprising the steps of:
forming, on a substrate, a resist film made of a resist material including a monomer containing a halogen atom and stable to acid, a polymer containing fluorine and stable to acid, a polymer containing an acid-labile group, and a photo acid generator;
performing pattern exposure by selectively irradiating the resist film with exposing light; and
developing the resist film after the pattern exposure to form a resist pattern from the resist film.

8. The method of claim 7, wherein
in the step of performing pattern exposure, the resist film is selectively irradiated with the exposing light while liquid is provided on the resist film.

9. The method of claim 8, wherein
the halogen atom is fluorine, chlorine, bromine, or iodine.

10. The method of claim 9, wherein
the halogen atom is fluorine, and
the monomer containing fluorine and stable to acid is perfluoro(propyl vinyl ether), 2,2,2-trifluoroethyl acrylate, 2,2,2-trifluoroethyl methacrylate, 2,2,3,3-tetrafluoropropyl acrylate, 1H,1H,5H-octafluoropentyl acrylate, 1H,1H,5H-octafluoropentyl methacrylate, perfluoroethyl acrylate, vinylhexafluoroisopropyl alcohol, α-trifluoromethyl acrylate, or norbornene-5-methylenehexafluoroisopropyl alcohol.

11. The method of claim 8, wherein
the polymer containing fluorine and stable to acid is poly(perfluoroethyl acrylate), polyvinylhexafluoroisopropyl alcohol, poly(α-trifluoromethyl acrylate), or poly(norbornene-5-methylenehexafluoroisopropyl alcohol).

12. The method of claim 8, wherein
the halogen atom is fluorine, and
the monomer is a constitutional unit of the polymer containing fluorine and stable to acid.

13. The method of claim 8, wherein
the liquid is water.

14. The method of claim 8, wherein
the exposing light is KrF excimer laser light, Xe₂ laser light, ArF excimer laser light, F₂ laser light, KrAr laser light, or Ar₂ laser light.

15. The method of claim 7, wherein
the exposing light is KrF excimer laser light, Xe₂ laser light, ArF excimer laser light, F₂ laser light, KrAr laser light, Ar₂ laser light, extreme ultraviolet, or an electron beam.

16. A method for forming a pattern, comprising the steps of:
forming, on a substrate, a resist film made of a resist material including an organic low-molecular-weight compound with a molecular weight of 1000 or less containing a halogen atom and stable to acid, a polymer containing fluorine and stable to acid, a polymer containing an acid-labile group, and a photo acid generator;
performing pattern exposure by selectively irradiating the resist film with exposing light; and
developing the resist film after the pattern exposure to form a resist pattern from the resist film,
wherein
the organic low-molecular-weight compound is a compound containing chlorine, bromine, or iodine, perfluoro-n-butanecarboxylic acid, perfluoro-n-hexanecarboxylic acid, perfluoroacetone, 3,4-difluorobenzyl alcohol, or perfluorotripropylamine.

17. The method of claim 16, wherein
in the step of performing pattern exposure, the resist film is selectively irradiated with the exposing light while liquid is provided on the resist film.

18. The method of claim 17
the liquid is water.

19. The method of claim 17, wherein
the exposing light is KrF excimer laser light, Xe₂ laser light, ArF excimer laser light, F₂ laser light, KrAr laser light, or Ar₂ laser light.

20. The method of claim 16, wherein
the exposing light is KrF excimer laser light, Xe₂ laser light, ArF excimer laser light, F₂ laser light, KrAr laser light, Ar₂ laser light, extreme ultraviolet, or an electron beam.
